(19) United States
(12) Patent Application Publication
(10) Pub. No.: US 2023/0378335 A1
(43) Pub. Date: Nov. 23, 2023

(54) SEMICONDUCTOR DEVICE

(71) Applicant: SAMSUNG ELECTRONICS CO., LTD., Suwon-si (KR)

(72) Inventors: Sung Keun LIM, Suwon-si (KR); Hyo Hoon BYEON, Suwon-si (KR); Do Hyun GO, Suwon-si (KR); Un Ki KIM, Suwon-si (KR); Yu Yeong JO, Suwon-si (KR); Jin Yeong CHO, Suwon-si (KR)

(73) Assignee: SAMSUNG ELECTRONICS CO., LTD., Suwon-si (KR)

(21) Appl. No.: 18/076,639

(22) Filed: Dec. 7, 2022

(30) Foreign Application Priority Data
May 23, 2022 (KR) 10-2022-0062708

(51) Int. Cl. H01L 29/775; H01L 29/06; H01L 29/16; H01L 29/165; H01L 29/423; H01L 21/02; H01L 29/66

(52) U.S. Cl. CPC H01L 29/775; H01L 29/0673; H01L 29/1608; H01L 29/165; H01L 29/42392; H01L 21/02603; H01L 21/02529; H01L 21/02532; H01L 29/66068

(57) ABSTRACT

The present disclosure provides a semiconductor device with a multi-bridge channel field effect transistor. In some embodiments, a semiconductor device includes a substrate, an active pattern that extends in a first horizontal direction on the substrate, a first nanosheet, a second nanosheet, and a gate electrode. The first nanosheet is spaced apart from the active pattern in a vertical direction, and includes a first layer, a second layer disposed on and in contact with the first layer, and a third layer disposed on and in contact with the second layer. The first and third layers include a first material, and the second layer includes a different second material. The second nanosheet is disposed on the first nanosheet and spaced apart from the first nanosheet in the vertical direction. The gate electrode extends in a second horizontal direction on the active pattern and surrounds the first and second nanosheets.

### CROSS-REFERENCE TO RELATED APPLICATIONS

This application claims benefit of priority under 35 U.S.C. § 119 to Korean Patent Application No. 10-2022-0062708, filed on May 23, 2022, in the Korean Intellectual Property Office, the disclosure of which is incorporated by reference herein in its entirety.

### BACKGROUND

### 1. Field

The present disclosure relates to semiconductor devices, and in particular, to semiconductor devices including a multi-bridge channel field effect transistor (MBCFET™).

### 2. Description of Related Art

As one of scaling techniques for increasing the density of an integrated circuit device, a multi-gate transistor including a silicon body of a fin-shape or nanowire shape on a substrate and a gate on the surface of the silicon body has been proposed.

In such a multi-gate transistor, since a three-dimensional channel is used, scaling may be relatively easy when compared to other related transistors. Further, although the gate length of the multi-gate transistor may not be increased, the current controllability may be improved. In addition, it may be possible to effectively suppress a short channel effect (SCE) in which the potential of a channel region is affected by a drain voltage.

### SUMMARY

The present disclosure provides a semiconductor device that may improve a short channel effect (SCE) by disposing a layer including silicon carbide (SiC) inside a nanosheet including silicon (Si).

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to an aspect of the present disclosure, a semiconductor device includes a substrate, an active pattern that extends in a first horizontal direction on the substrate, a first nanosheet, a second nanosheet, and a gate electrode. The first nanosheet is spaced apart from the active pattern in a vertical direction, and includes a plurality of layers. The plurality of layers includes a first layer, a second layer disposed on the first layer and in contact with the first layer, and a third layer disposed on the second layer and in contact with the second layer. The first layer and the third layer include a first material, and the second layer includes a second material that is different from the first material. The second nanosheet is disposed on the first nanosheet and spaced apart from the first nanosheet in the vertical direction. The gate electrode extends in a second horizontal direction on the active pattern and surrounds the first nanosheet and the second nanosheet. The second horizontal direction is different from the first horizontal direction.

According to an aspect of the present disclosure, a semiconductor device includes a substrate, an active pattern which that extends in a first horizontal direction on the substrate, a first nanosheet, a gate electrode, and a source/drain region. The first nanosheet is spaced apart from the active pattern in a vertical direction, and includes a plurality of layers. The plurality of layers includes a first layer containing silicon (Si), a second layer disposed on the first layer and in contact with the first layer and containing silicon carbide (SiC), and a third layer disposed on the second layer and in contact with the second layer and containing silicon (Si). The gate electrode extends in a second horizontal direction on the active pattern and surrounds the first nanosheet. The second horizontal direction is different from the first horizontal direction. The source/drain region is disposed on at least one side of the gate electrode in the first horizontal direction, and is in contact with each sidewall in the first horizontal direction of the plurality of layers.

According to an aspect of the present disclosure, a semiconductor device includes a substrate, an active pattern that extends in a first horizontal direction on the substrate, a plurality of nanosheets that are stacked and spaced apart from the active pattern in a vertical direction, a gate electrode that extends in a second horizontal direction on the active pattern and surrounds the plurality of nanosheets, a source/drain region disposed on at least one side of the gate electrode in the first horizontal direction, a gate insulation layer disposed between the plurality of nanosheets and the gate electrode, and an interface layer disposed between the plurality of nanosheets and the gate insulation layer. The second horizontal direction is different from the first horizontal direction. Each of the plurality of nanosheets includes a plurality of layers. The plurality of layers includes a first layer containing silicon (Si), a second layer disposed on the first layer and in contact with the first layer and containing silicon carbide (SiC), and a third layer disposed on the second layer and in contact with the second layer and containing silicon (Si). A first sidewall in the first horizontal direction of each of the plurality of layers is in contact with the source/drain region. A second sidewall in the second horizontal direction of each of the plurality of layers is in contact with the interface layer. A second thickness of the second layer in the vertical direction is less than a first thickness of the first layer in the vertical direction. The second thickness of the second layer in the vertical direction is less than a third thickness of the third layer in the vertical direction.

It should be noted that the effects of the present disclosure are not limited to those described above, and other effects of the present disclosure will be apparent from the following description.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is a schematic layout diagram of a semiconductor device, according to some embodiments of the present disclosure;

FIG. 2 is a cross-sectional view taken along line A-A′ of FIG. 1, according to some embodiments of the present disclosure;

FIG. 3 is a cross-sectional view taken along line B-B′ of FIG. 1, according to some embodiments of the present disclosure;

FIG. 4 is an enlarged view of portion R of FIG. 3, according to some embodiments of the present disclosure;

FIGS. 5 to 15 are views illustrating intermediate stages of fabrication, provided to explain a method of fabricating a semiconductor device, according to some embodiments of the present disclosure;

FIG. 16 is an enlarged view for describing a semiconductor device, according to some embodiments of the present disclosure;

FIG. 17 is an enlarged view for describing a semiconductor device, according to some embodiments of the present disclosure;

FIG. 18 is an enlarged view for describing a semiconductor device, according to some embodiments of the present disclosure;

FIG. 19 is an enlarged view for describing a semiconductor device, according to some embodiments of the present disclosure;

FIG. 20 is an enlarged view for describing a semiconductor device, according to some embodiments of the present disclosure;

FIG. 21 is an enlarged view for describing a semiconductor device, according to some embodiments of the present disclosure;

FIG. 22 is an enlarged view for describing a semiconductor device, according to some embodiments of the present disclosure; and

FIG. 23 is a cross-sectional view for describing a semiconductor device, according to some embodiments of the present disclosure.

### DETAILED DESCRIPTION

In the following detailed description, only certain embodiments of the present invention have been shown and described, simply by way of illustration. As those skilled in the art would realize, the described embodiments may be modified in various different ways, all without departing from the spirit or scope of the present invention.

Accordingly, the drawings and description are to be regarded as illustrative in nature and not restrictive, and like reference numerals designate like elements throughout the specification disclosure. In the flowcharts described with reference to the drawings in this specification disclosure, the operation order may be changed, various operations may be merged, certain operations may be divided, and certain operations may not be performed.

An expression recited in the singular may be construed as singular or plural unless the expression “one”, “single”, etc., is used. Terms including ordinal numbers such as first, second, and the like, will be used only to describe various components, and are not to be interpreted as limiting these components. The terms may be only used to differentiate one component from others.

It will be understood that, although the terms first, second, third, fourth, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the disclosure.

As is traditional in the field, the embodiments are described, and illustrated in the drawings, in terms of functional blocks, units and/or modules. Those skilled in the art will appreciate that these blocks, units and/or modules are physically implemented by electronic (or optical) circuits such as logic circuits, discrete components, microprocessors, hard-wired circuits, memory elements, wiring connections, and the like, which may be formed using semiconductor-based fabrication techniques or other manufacturing technologies. In the case of the blocks, units and/or modules being implemented by microprocessors or similar, they may be programmed using software (e.g., microcode) to perform various functions discussed herein and may optionally be driven by firmware and/or software. In embodiments, each block, unit and/or module may be implemented by dedicated hardware, or as a combination of dedicated hardware to perform some functions and a processor (e.g., one or more programmed microprocessors and associated circuitry) to perform other functions. Also, each block, unit and/or module of the embodiments may be physically separated into two or more interacting and discrete blocks, units and/or modules without departing from the present scope. Further, the blocks, units and/or modules of the embodiments may be physically combined into more complex blocks, units and/or modules without departing from the present scope.

The term “coupled” (or connected) as used throughout the specification of this disclosure (including claims of the present disclosure) may refer to any direct or indirect means of connection. For example, if it is described in the text that a first device is coupled (or connected) to a second device, it should be interpreted that the first device can be directly connected to the second device, or the first device can be indirectly connected to the second device through another device or some other connection means. Terms such as “first” and “second” mentioned in the full text of the description (including claims of the present disclosure) are used to name the elements or to distinguish different embodiments or scopes, rather than to limit the upper or lower limit of the number of elements, nor is it intended to limit the order of the elements. Also, where possible, elements/components/steps denoted by the same reference numerals in the drawings and embodiments represent the same or similar parts. Elements/components/steps that are denoted by the same reference numerals or the same terminology in different embodiments may serve as cross reference for each other.

Hereinafter, embodiments of the present disclosure are described with reference to the attached drawings.

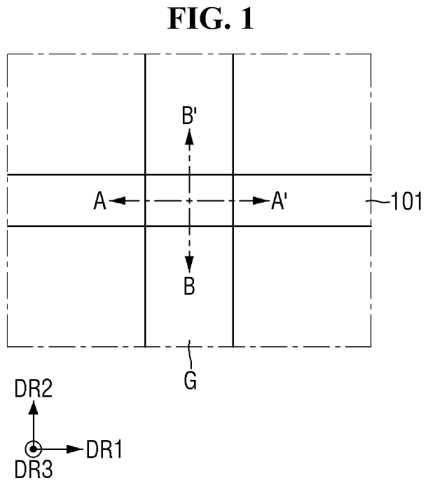

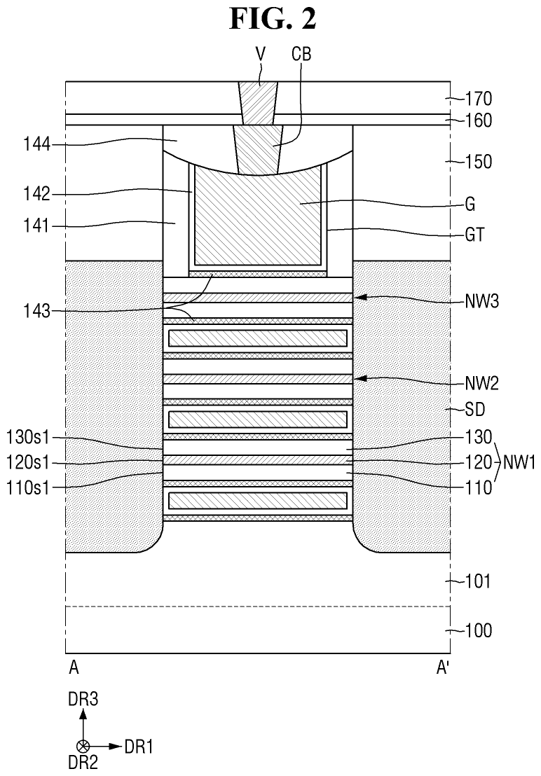

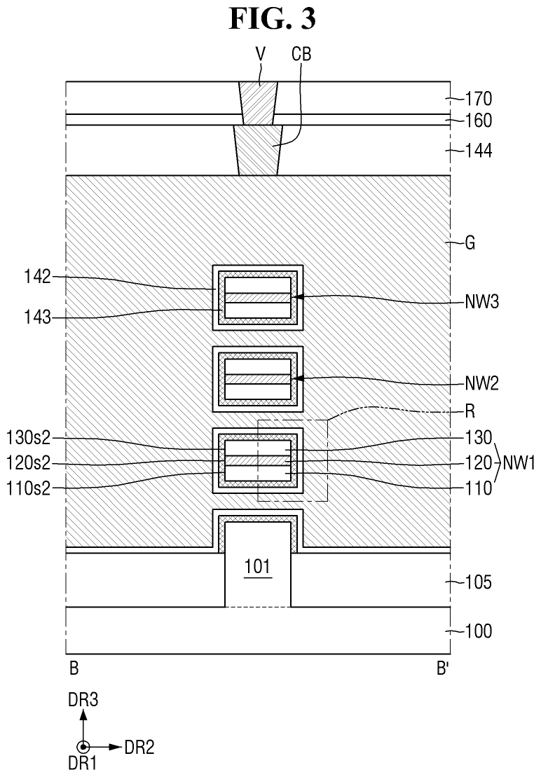

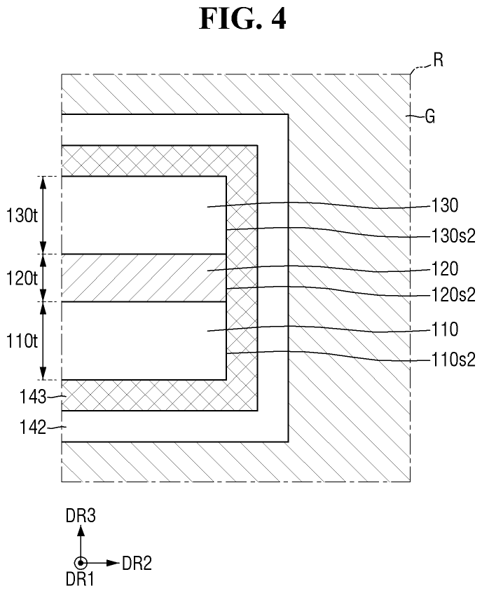

FIG. 1 is a schematic layout diagram of a semiconductor device according to some embodiments of the present disclosure. FIG. 2 is a cross-sectional view taken along line A-A′ of FIG. 1. FIG. 3 is a cross-sectional view taken along line B-B′ of FIG. 1. FIG. 4 is an enlarged view of portion R of FIG. 3.

Referring to FIGS. 1 to 4, a semiconductor device according to some embodiments of the present disclosure includes a substrate 100, an active pattern 101, a field insulation layer 105, first to third nanosheets NW1, NW2, and NW3, a gate electrode G, a gate spacer 141, an interface layer 143, a capping pattern 144, a source/drain region SD, a first interlayer insulation layer 150, an etch stop layer 160, a second interlayer insulation layer 170, a gate contact CB, and a via V.

The substrate 100 may be a silicon substrate or a silicon-on-insulator (SOI). Alternatively or additionally, the substrate 100 may include silicon germanium, silicon germanium on insulator (SGOI), indium antimonide, lead tellurium compound, indium arsenide, indium phosphide, gallium arsenide, or gallium antimonide. That is, the present disclosure is not limited in this regard.

The active pattern 101 may extend in a first horizontal direction DR1 on the substrate 100. The active pattern 101 may protrude from the substrate 100 in a vertical direction DR3. Hereinafter, a second horizontal direction DR2 may refer to a direction different from the first horizontal direction DR1, and the vertical direction DR3 may refer to a direction perpendicular to each of the first and second horizontal directions DR1 and DR2.

The active pattern 101 may be a part of the substrate 100, and may include an epitaxial layer that is grown from the substrate 100 (not shown). The active pattern 101 may include, for example, silicon and/or germanium, which is an elemental semiconductor material. Further, the active pattern 101 may contain compound semiconductors, and may contain, for example, a group IV-IV compound semiconductor or a group III-V compound semiconductor.

The field insulation layer 105 may be disposed on the substrate 100. The field insulation layer 105 may surround sidewalls of the active pattern 101. The active pattern 101 may protrude further in the vertical direction DR3 than an upper surface of the field insulation layer 105. However, the present disclosure is not limited thereto. The field insulation layer 105 may include, for example, silicon oxide, silicon nitride, silicon oxynitride, or any combination thereof.

A plurality of nanosheets may be disposed on the active pattern 101. The plurality of nanosheets may be disposed at a portion where the active pattern 101 crosses the gate electrode G. Although FIGS. 2 and 3 depict that the plurality of nanosheets include three nanosheets spaced apart from each other and stacked in the vertical direction DR3, this is merely for convenience of description and the present disclosure is not limited thereto. In some embodiments, four or more nanosheets stacked and spaced apart from each other in the vertical direction DR3 may be included. Hereinafter, an example in which the plurality of nanosheets include three nanosheets spaced apart from each other and stacked in the vertical direction DR3 is described.

For example, the plurality of nanosheets may include the first to third nanosheets NW1, NW2, and NW3 that are spaced apart from each other and stacked in the vertical direction DR3. The first nanosheet NW1 may be on the active pattern 101 and spaced apart from the active pattern 101 in the vertical direction DR3. The second nanosheet NW2 may be on the first nanosheet NW1 and spaced apart from the first nanosheet NW1 in the vertical direction DR3. The third nanosheet NW3 may be on the second nanosheet NW2 and spaced apart from the second nanosheet NW2 in the vertical direction DR3.

The first nanosheet NW1 may include first to third layers 110, 120, and 130 that may be sequentially stacked on one another. The first layer 110 may be on the active pattern 101 and spaced apart from the active pattern 101 in the vertical direction DR3. The second layer 120 may be disposed on the first layer 110. The second layer 120 may be in contact with an upper surface of the first layer 110. The third layer 130 may be disposed on the second layer 120. The third layer 130 may be in contact with an upper surface of the second layer 120.

In some embodiments, the first layer 110 and the third layer 130 may be formed of or include the same material as each other. The second layer 120 may be formed of or include a different material from that of each of the first and third layers 110 and 130. For example, each of the first layer 110 and the third layer 130 may include silicon (Si). For another example, the second layer 120 may include silicon carbide (SiC). Alternatively or additionally, a lattice structure of each of the first to third layers 110, 120, and 130 may be the same.

In some embodiments, a thickness 120t of the second layer 120 in the vertical direction DR3 may be different from a thickness 110t of the first layer 110 in the vertical direction DR3 and a thickness 130t of the third layer 130 in the vertical direction DR3. For example, the thickness 120t of the second layer 120 in the vertical direction DR3 may be less than the thickness 110t of the first layer 110 in the vertical direction DR3 and the thickness 130t of the third layer 130 in the vertical direction DR3. For another example, the thickness 130t of the third layer 130 in the vertical direction DR3 and the thickness 110t of the first layer 110 in the vertical direction DR3 may be the same as each other. That is, the present disclosure is not limited thereto.

In some embodiments, a sidewall 110s2 of the first layer 110 in the second horizontal direction DR2, a sidewall 120s2 of the second layer 120 in the second horizontal direction DR2, and a sidewall 130s2 of the third layer 130 in the second horizontal direction DR2 may be aligned with one another in the vertical direction DR3. For example, the sidewall 110s2 of the first layer 110 in the second horizontal direction DR2, the sidewall 120s2 of the second layer 120 in the second horizontal direction DR2, and the sidewall 130s2 of the third layer 130 in the second horizontal direction DR2 may each be aligned with the sidewall of the active pattern 101 in the vertical direction DR3. However, the present disclosure is not limited thereto.

Each of the second nanosheet NW2 and the third nanosheet NW3 may have a similar structure to that of the first nanosheet NW1. Thus, detailed descriptions of the second nanosheet NW1 and the third nanosheet NW3 are not provided for the sake of brevity.

The gate spacer 141 may extend in the second horizontal direction DR2 on the third nanosheet NW3 and the field insulation layer 105. The gate spacer 141 may include two spacers that are spaced apart from each other in the first horizontal direction DR1. A gate trench GT may be defined between the two spacers of the gate spacer 141. The gate spacer 141 may include at least one of, for example, silicon nitride (SiN), silicon oxynitride (SiON), silicon oxide (SiO₂), silicon oxycarbonitride (SiOCN), silicon boron nitride (SiBN), silicon oxyboron nitride (SiOBN), silicon oxycarbide (SiOC), or a combination thereof.

The gate electrode G may extend in the second horizontal direction DR2 on the active pattern 101 and the field insulation layer 105. The gate electrode G may be disposed inside the gate trench GT. Alternatively or additionally, the gate trench GT may surround each of the first to third nanosheets NW1, NW2, and NW3.

The gate electrode G may include at least one of, for example, titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlC—N), titanium aluminum carbide (TiAlC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), or a combination thereof. The gate electrode G may include, for example, a conductive metal oxide, a conductive metal oxynitride, or the like, and may include an oxidized form of the materials described above.

The gate insulation layer 142 may be disposed along sidewalls and a bottom surface of the gate trench GT. That is, the gate insulation layer 142 may be disposed between the gate spacer 141 and the gate electrode G, inside the gate trench GT. The gate insulation layer 142 may be disposed between the gate electrode G and the active pattern 101. The gate insulation layer 142 may be disposed between the gate electrode G and the source/drain region SD.

The gate insulation layer 142 may be disposed between the gate electrode G and each of the first to third nanosheets NW1, NW2, and NW3. The gate insulation layer 142 may be disposed between the gate electrode G and an upper surface of each of the first to third nanosheets NW1, NW2, and NW3. Alternatively or additionally, the gate insulation layer 142 may be disposed between the gate electrode G and a bottom surface of each of the first to third nanosheets NW1, NW2, and NW3.

In some embodiments, the gate insulation layer 142 may be disposed between the gate electrode G and the sidewall in the second horizontal direction DR2 of each of the first to third nanosheets NW1, NW2, and NW3. For example, the gate insulation layer 142 may be disposed between the gate electrode G and the sidewall 100s2 in the second horizontal direction DR2 of the first layer 110. The gate insulation layer 142 may be disposed between the gate electrode G and the sidewall 120s2 in the second horizontal direction DR2 of the second layer 120. The gate insulation layer 142 may be disposed between the gate electrode G and the sidewall 130s2 in the second horizontal direction DR2 of the third layer 130.

The gate insulation layer 142 may include at least one of silicon oxide, silicon nitride, silicon oxynitride, or a high dielectric constant material having a higher dielectric constant than that of silicon oxide. For example, the high-dielectric constant material may include one or more of hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate.

A semiconductor device according to some embodiments may include a negative capacitance field-effect transistor (FET) including a negative capacitor. For example, the gate insulation layer 142 may include a ferroelectric film exhibiting a ferroelectric property and a paraelectric film exhibiting a paraelectric property.

The ferroelectric film may have a negative capacitance, and the paraelectric film may have a positive capacitance. For example, in the case where two or more capacitors are connected in series and each capacitor has a positive capacitance, a total capacitance may be reduced to a value that is less than a capacitance of each of the capacitors. In contrast, in the case where at least one of serially-connected capacitors has a negative capacitance, a total capacitance of the serially-connected capacitors may have a positive value and may be greater than an absolute value of each capacitance.

In the case where a ferroelectric film having a negative capacitance and a paraelectric film having a positive capacitance are connected in series, a total capacitance of the serially-connected ferroelectric and paraelectric films may be increased. Due to such an increase of the total capacitance, a transistor including the ferroelectric film may have a subthreshold swing (SS), which may be less than 60 mV/decade, at room temperature.

The ferroelectric film may have the ferroelectric property. The ferroelectric film may be formed of or include at least one of, for example, hafnium oxide, hafnium zirconium oxide, barium strontium titanium oxide, barium titanium oxide, and/or lead zirconium titanium oxide. Here, the hafnium zirconium oxide may be hafnium oxide that is doped with zirconium (Zr). In another example, the hafnium zirconium oxide may be a compound composed of hafnium (Hf), zirconium (Zr), and/or oxygen (O).

The ferroelectric film may further include dopants. For example, the dopants may include at least one of aluminum (Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr), and/or tin (Sn). The kind of the dopants in the ferroelectric film may vary depending on a ferroelectric material included in the ferroelectric film.

In the case where the ferroelectric film includes hafnium oxide, the dopants in the ferroelectric film may include at least one of, for example, gadolinium (Gd), silicon (Si), zirconium (Zr), aluminum (Al), and/or yttrium (Y).

In the case where the dopant is aluminum (Al), a content of aluminum in the ferroelectric film may range from 3 to 8 atomic percentage (at %). For example, the content of the aluminum as the dopant may be a ratio of the number of aluminum atoms to the number of hafnium and aluminum atoms.

In the case where the dopant is silicon (Si), a content of silicon in the ferroelectric film may range from 2 at % to 10 at %. In the case where the dopant is yttrium (Y), a content of yttrium in the ferroelectric film may range from 2 at % to 10 at %. In the case where the dopant is gadolinium (Gd), a content of gadolinium in the ferroelectric film may range from 1 at % to 7 at %. In the case where the dopant is zirconium (Zr), a content of zirconium in the ferroelectric film may range from 50 at % to 80 at %.

The paraelectric film may have the paraelectric property. The paraelectric film may be formed of or include at least one of, for example, silicon oxide and/or high-dielectric constant metal oxide. The metal oxides, which may be used as the paraelectric film, may include at least one of, for example, hafnium oxide, zirconium oxide, and/or aluminum oxide, but the present disclosure is not limited thereto.

The ferroelectric film and the paraelectric film may be formed of or include the same material. The ferroelectric film may have the ferroelectric property, but the paraelectric film may not have the ferroelectric property. For example, in the case where the ferroelectric and paraelectric films contain hafnium oxide, a crystal structure of the hafnium oxide in the ferroelectric film may be different from a crystal structure of the hafnium oxide in the paraelectric film.

The ferroelectric film may exhibit the ferroelectric property, only when its thickness is in a specific range. The ferroelectric film may have a thickness ranging from 0.5 to 10 nanometers (nm), but the present disclosure is not limited thereto. Since a critical thickness associated with the occurrence of the ferroelectric property varies depending on the kind of the ferroelectric material, the thickness of the ferroelectric film may be changed depending on the kind of the ferroelectric material.

As an example, the gate insulation layer 142 may include a single ferroelectric film. As another example, the gate insulation layer 142 may include a plurality of ferroelectric films spaced apart from each other. The gate insulation layer 142 may have a multi-layered structure, in which a plurality of ferroelectric films and a plurality of paraelectric films are alternately stacked.

The interface layer 143 may be disposed between the gate insulation layer 142 and each of the first to third nanosheets NW1, NW2, and NW3. The interface layer 143 may be disposed between the gate electrode G and the upper surface of each of the first to third nanosheets NW1, NW2, and NW3. The interface layer 143 may be disposed between the gate electrode G and the bottom surface of each of the first to third nanosheets NW1, NW2, and NW3. For example, the interface layer 143 may be in contact with each of the first to third nanosheets NW1, NW2, and NW3. For another example, the interface layer 143 may be in contact with the upper surface and bottom surface of each of the first to third nanosheets NW1, NW2, and NW3.

In some embodiments, the interface layer 143 may be disposed between the gate insulation layer 142 and the sidewall in the second horizontal direction DR2 of each of the first to third nanosheets NW1, NW2, and NW3. For example, the interface layer 143 may be disposed between the gate insulation layer 142 and the sidewall 100s2 in the second horizontal direction DR2 of the first layer 110. The interface layer 143 may be in contact with the sidewall 110s2 in the second horizontal direction DR2 of the first layer 110. The interface layer 143 may be disposed between the gate insulation layer 142 and the sidewall 120s2 in the second horizontal direction DR2 of the second layer 120. The interface layer 143 may be in contact with the sidewall 120s2 in the second horizontal direction DR2 of the second layer 120. The interface layer 143 may be disposed between the gate insulation layer 142 and the sidewall 130s2 in the second horizontal direction DR2 of the third layer 130. The interface layer 143 may be in contact with the sidewall 130s2 in the second horizontal direction DR2 of the third layer 130. The interface layer 143 may include silicon oxide SiO2. However, the present disclosure is not limited thereto.

The capping pattern 144 may extend in the second horizontal direction DR2 on the gate electrode G and the gate spacer 141. For example, the capping pattern 144 may be in contact with the upper surface of the gate spacer 141. However, the present disclosure is not limited thereto. In some embodiments, the capping pattern 144 may be disposed between the gate spacers 141. In this case, an upper surface of the capping pattern 144 may be coplanar with the upper surfaces of the gate spacers 141. The capping pattern 144 may include at least one of, for example, silicon nitride (SiN), silicon oxynitride (SiON), silicon oxide (SiO2), silicon carbonitride (SiCN), silicon oxycarbonitride (SiOCN), and/or a combination thereof.

The source/drain region SD may be on the active pattern 101 and disposed on at least one side of each of the first to third nanosheets NW1, NW2, and NW3. For example, the source/drain region SD may be on the active pattern 101 and disposed on both sides of each of the first to third nanosheets NW1, NW2, and NW3.

The source/drain region SD may be in contact with each of the first to third nanosheets NW1, NW2, and NW3. For example, the source/drain region SD may be in contact with the sidewall 110s1 in the first horizontal direction DR1 of the first layer 110. The source/drain region SD may be in contact with the sidewall 120s1 in the first horizontal direction DR1 of the second layer 120. The source/drain region SD may be in contact with the sidewall 130s1 in the first horizontal direction DR1 of the third layer 130. Although FIG. 2 depicts that an upper surface of the source/drain region SD is formed to be higher than the upper surface of the third nanosheet NW3, the present disclosure is not limited thereto.

The first interlayer insulation layer 150 may be disposed on the field insulation layer 105. The first interlayer insulation layer 150 may surround the source/drain region SD. The first interlayer insulation layer 150 may surround the sidewalls of the gate spacer 141. For example, the upper surface of the first interlayer insulation layer 150 may be coplanar with the upper surface of the capping pattern 144. However, the present disclosure is not limited thereto.

The first interlayer insulation layer 150 may include at least one of, for example, silicon oxide, silicon nitride, silicon oxycarbide, silicon oxynitride, silicon oxycarbonitride, or a low-dielectric constant material. The low-dielectric constant material may include, for example, fluorinated tetraethylorthosilicate (FTEOS), hydrogen silsesquioxane (HSQ), bis-benzocyclobutene (BCB), tetramethylorthosilicate (TMOS), octamethyleyclotetrasiloxane (OMCTS), hexamethyldisiloxane (HMDS), trimethylsilyl borate (TMSB), diacetoxyditertiarybutosiloxane (DADBS), trimethylsilil phosphate (TMSP), polytetrafluoroethylene (PTFE), tonen silazen (TOSZ), fluoride silicate glass (FSG), polyimide nanofoams such as polypropylene oxide, carbon-doped silicon oxide (CDO), organo silicate glass (OSG), SiLK, amorphous fluorinated carbon, silica aerogels, silica xerogels, mesoporous silica or a combination thereof, but the present disclosure is not limited thereto.

The gate contact CB may be disposed on the gate electrode G. The gate contact CB may penetrate through the capping pattern 144 in the vertical direction DR3 and may be connected to the gate electrode G. For example, an upper surface of the gate contact CB may be coplanar with the upper surface of the first interlayer insulation layer 150. However, the present disclosure is not limited thereto. Although FIGS. 2 and 3 depict that the gate contact CB is a single film, this is merely for convenience of description and the present disclosure is not limited thereto. In other embodiments, the gate contact CB may be formed as a multi-film. The gate contact CB may include a conductive material.

The etch stop layer 160 may be disposed on the upper surfaces of the first interlayer insulation layer 150 and the capping pattern 144. The etch stop layer 160 may be formed, for example, in a conformal manner. Although FIGS. 2 and 3 depict that the etch stop layer 160 is a single layer, the present disclosure is not limited thereto. In some embodiments, the etch stop layer 160 may be a multilayer. The etch stop layer 160 may include at least one of, for example, aluminum oxide, aluminum nitride, hafnium oxide, zirconium oxide, silicon oxide, silicon nitride, silicon oxycarbonitride, and/or a low-dielectric constant material.

The second interlayer insulation layer 170 may be disposed on the etch stop layer 160. The second interlayer insulation layer 170 may include at least, for example, silicon oxide, silicon nitride, silicon oxynitride, and/or a low-dielectric constant material.

The via V may penetrate through the second interlayer insulation layer 170 and the etch stop layer 160 in the vertical direction DR3 and may be connected to the gate contact CB. Although FIGS. 2 and 3 depict that the via V is formed as a single film, this is merely for convenience of description and the present disclosure is not limited thereto. That is, the via V may be formed as a multi-film. The via V may include a conductive material.

In the semiconductor device according to some embodiments of the present disclosure, a layer including silicon carbide (SiC) having a higher energy gap than silicon (Si) is disposed in the nanosheet to increase energy-band offset for electrons or holes. Accordingly, the semiconductor device according to some embodiments of the present disclosure may improve a short channel effect without reducing the thickness of the nanosheet.

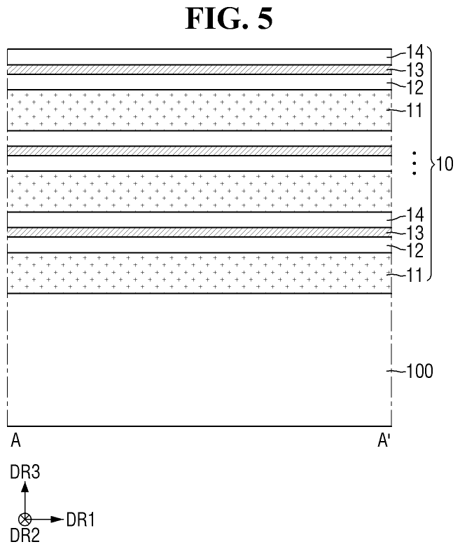

Hereinafter, a method of fabricating a semiconductor device according to some embodiments of the present disclosure are described with reference to FIGS. 5 to 15.

FIGS. 5 to 15 are views illustrating intermediate stages of fabrication, provided to explain a method of fabricating a semiconductor device according to some embodiments of the present disclosure.

Referring to FIG. 5, a stack structure 10 may be formed on the substrate 100. The stack structure 10 may include a sacrificial layer 11, a first semiconductor layer 12, a second semiconductor layer 13, and a third semiconductor layer 14 that are alternately stacked on the substrate 100. For example, the sacrificial layer 11 may be formed on the lowermost portion of the stack structure 10, and the third semiconductor layer 14 may be formed on the uppermost portion of the stack structure 10. However, the present disclosure is not limited thereto. In some embodiments, the sacrificial layer 11 may be formed on the uppermost portion of the stack structure 10.

For example, the sacrificial layer 11 may include silicon germanium (SiGe). The second semiconductor layer 13 may be formed of or include a different material from that of each of the first semiconductor layer 12 and the third semiconductor layer 14. For another example, each of the first semiconductor layer 12 and the third semiconductor layer 14 may include silicon (Si). The second semiconductor layer 13 may include silicon carbide (SiC).

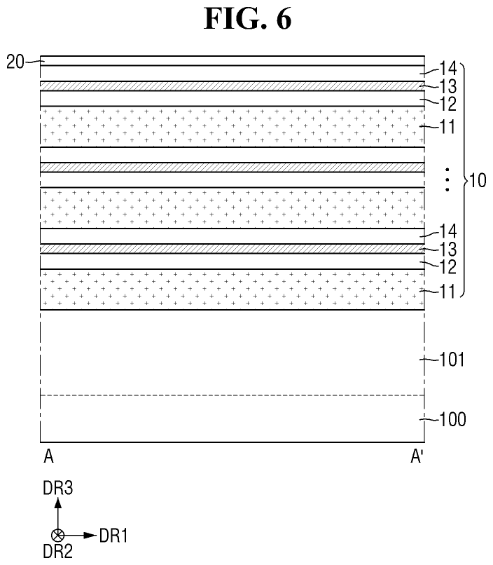

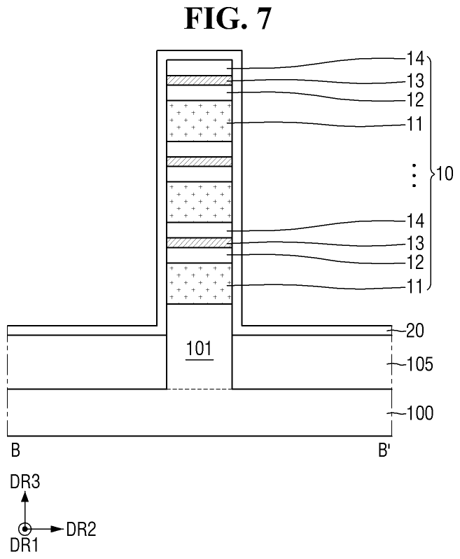

Referring to FIGS. 6 and 7, the stack structure 10 may be partially etched. The substrate 100 may also be partially etched while the stack structure 10 is being etched. By the etching process, the active pattern 101 may be defined in a lower portion of the stack structure 10 on the substrate 100. Thereafter, the field insulation layer 105 surrounding the sidewalls of the active pattern 101 may be formed. For example, the upper surface of the active pattern 101 may be formed higher than the upper surface of the field insulation layer 105.

Thereafter, a pad oxide layer 20 may be formed to cover the upper surface of the field insulation layer 105, the exposed sidewalls of the active pattern 101, and the sidewalls and upper surface of the stack structure 10. For example, the pad oxide layer 20 may be formed in a conformal manner. The pad oxide layer 20 may include, for example, silicon oxide (SiO₂).

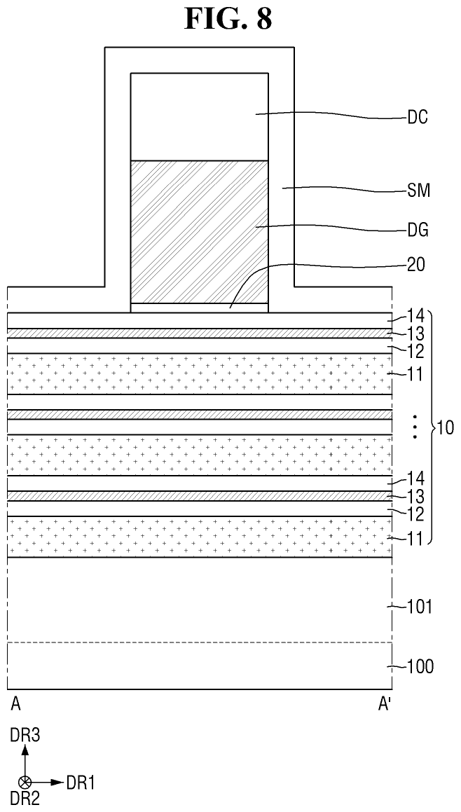

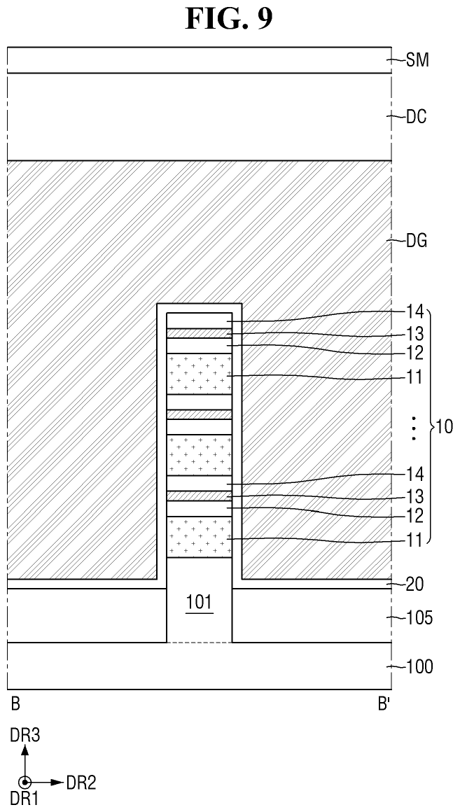

Referring to FIGS. 8 and 9, a dummy gate DG and a dummy capping pattern DC, each of which is above the stack structure 10 and the field insulation layer 105 and extends in the second horizontal direction DR2 on the pad oxide layer 20, may be formed. The dummy capping pattern DC may be formed on the dummy gate DG. The pad oxide layer 20 other than a portion that overlaps the dummy gate DG in the vertical direction DR3 on the substrate 100 may be removed while the dummy gate DG and the dummy capping pattern DC are being formed.

Thereafter, a spacer material layer SM may be formed to cover sidewalls of the dummy gate DG, the sidewalls and upper surface of the dummy capping pattern DC, and the exposed sidewalls and upper surface of the stack structure 10. The spacer material layer SM may be formed on the exposed upper surface of the field insulation layer 105 (not shown). For example, the spacer material layer SM may be formed in a conformal manner. The spacer material layer SM may include at least one of, for example, silicon nitride (SiN), silicon oxycarbonitride (SiOCN), silicon boron carbonitride (SiBCN), silicon carbonitride (SiCN), silicon oxynitride (SiON), and/or a combination thereof.

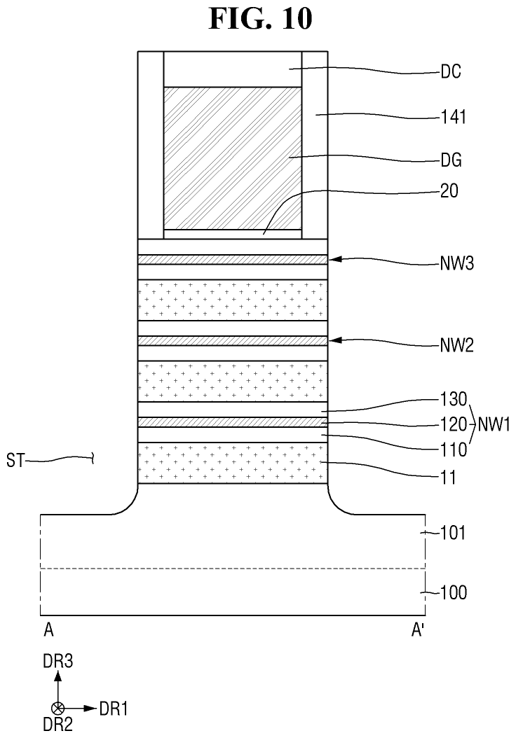

Referring to FIG. 10, the stack structure 10 (e.g., stack structure 10 in FIG. 8) may be etched using the dummy capping pattern DC and the dummy gate DG as a mask to form a source/drain trench ST. For example, the source/drain trench ST may extend through the active pattern 101.

The spacer material layer SM (e.g., spacer material layer SM in FIG. 8) and the dummy capping pattern DC which are formed on the upper surface of the dummy capping pattern DC may be partially removed while the source/drain trench ST is being formed. The spacer material layer SM remaining on the each sidewall of each of the dummy gate DG and the dummy capping pattern DC may be defined as a gate spacer 141.

After the source/drain trench ST is formed, the first semiconductor layer 12 (e.g., first semiconductor layer 12 in FIG. 8), the second semiconductor layer 13 (e.g., second semiconductor layer 13 in FIG. 8), and the third semiconductor layer 14 (e.g., third semiconductor layer 14 in FIG. 8) that remain under the dummy gate DG may be defined as the first layer 110, the second layer 120, and the third layer 130, respectively. Alternatively or additionally, the first to third layers 110, 120, and 130 spaced apart from each other in the vertical direction DR3 from the active pattern 101 may be defined as the first nanosheet NW1. Alternatively or additionally, the first to third layers 110, 120, and 130 spaced apart from each other in the vertical direction DR3 from the first nanosheet NW1 may be defined as the second nanosheet NW2. Alternatively or additionally, the first to third layers 110, 120, and 130 spaced apart from each other in the vertical direction DR3 from the second nanosheet NW2 may be defined as the third nanosheet NW3.

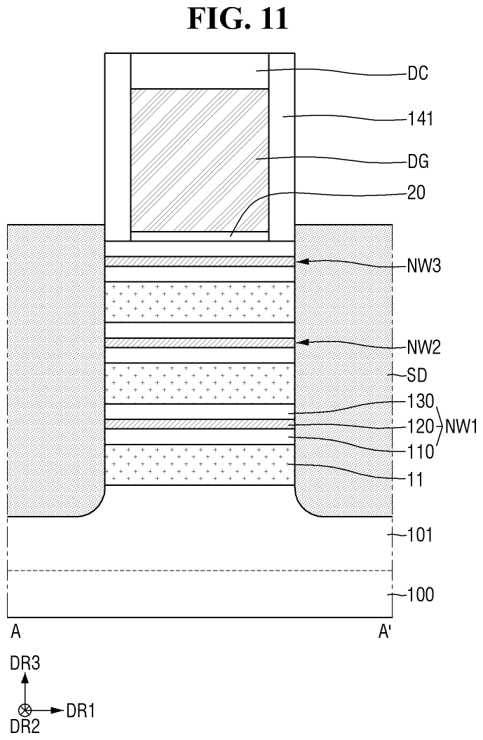

Referring to FIG. 11, the source/drain region SD may be formed inside the source/drain trench ST (e.g., source/drain trench ST in FIG. 10). The source/drain region SD may be formed by epitaxially growing from the first to third nanosheets NW1, NW2, and NW3 and the active pattern 101 that are exposed by the source/drain trench ST.

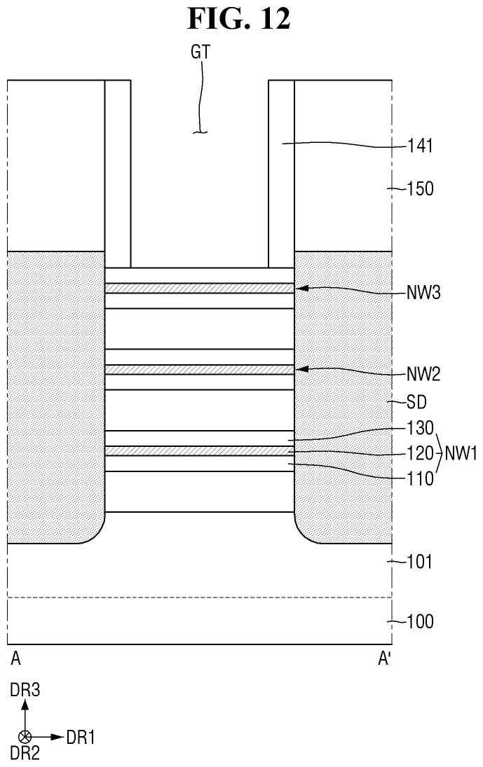

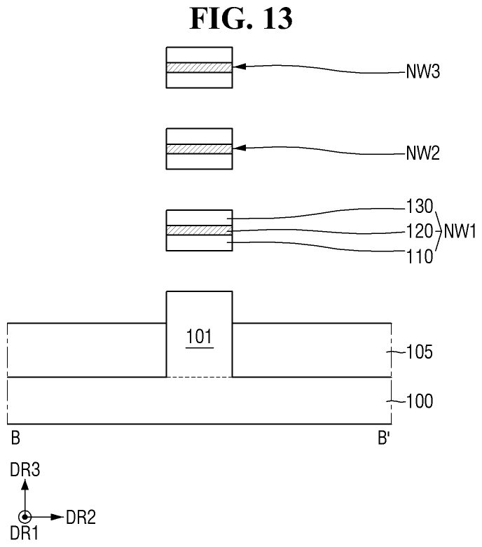

Referring to FIGS. 12 and 13, the first interlayer insulation layer 150 may be formed to cover each of the source/drain region SD, the gate spacer 141, and the dummy capping pattern DC (e.g., dummy capping pattern DC in FIG. 11). Thereafter, the upper surface of the dummy gate DG (e.g., dummy gate DG in FIG. 11) may be exposed through a planarization process. Then, the dummy gate DG, the pad oxide layer 20 (e.g., pad oxide layer 20 in FIG. 11), and the sacrificial layer 11 (e.g., sacrificial layer 11 in FIG. 11) may each be removed. A portion where the dummy gate DG is removed may be defined as the gate trench GT.

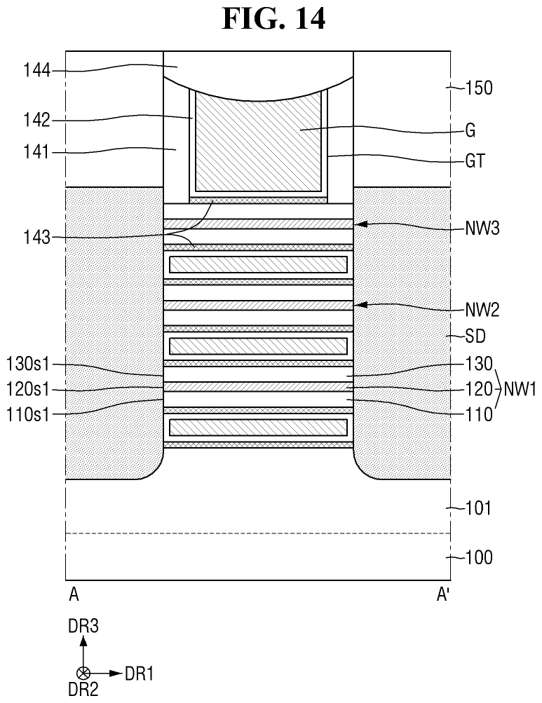

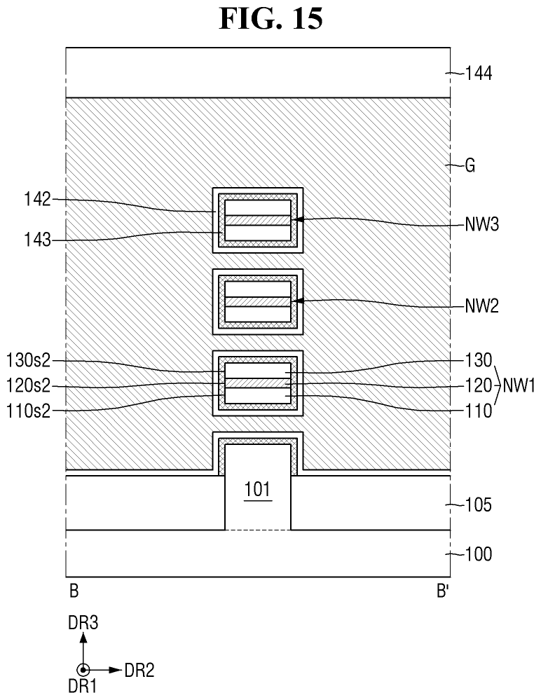

Referring to FIGS. 14 and 15, the interface layer 143 and the gate insulation layer 142 may be sequentially formed in portions where the dummy gate DG (e.g., dummy gate DG in FIG. 11), the pad oxide layer 20 (e.g., pad oxide layer 20 in FIG. 11), and the sacrificial layer 11 (e.g., sacrificial layer 11 in FIG. 11) are respectively removed. In some embodiments, the interface layer 143 may be formed on the exposed surface of each of the first to third nanosheets NW1, NW2, and NW3. The gate insulation layer 142 may be formed on the interface layer 143. For example, each of the interface layer 143 and the gate insulation layer 142 may be formed in a conformal manner.

Thereafter, the gate electrode G surrounding each of the first to third nanosheets NW1, NW2, and NW3 may be formed inside the gate trench GT and in a region overlapping the gate trench GT in the vertical direction DR3. Thereafter, the capping pattern 144 may be formed on each gate electrode G. For example, the capping pattern 144 may be formed in contact with the upper surface of the gate spacer 141, but the present disclosure is not limited thereto.

Referring to FIGS. 2 to 4, the gate contact CB that penetrates through the capping pattern 144 in the vertical direction DR3 and is connected to the gate electrode G may be formed. Then, the etch stop layer 160 and the second interlayer insulation layer 170 may be sequentially formed on each of the first interlayer insulation layer 150, the capping pattern 144, and the gate contact CB. Then, the via V that penetrates the second interlayer insulation layer 170 and the etch stop layer 160 in the vertical direction DR3 and is connected to the gate contact CB may be formed. Through this fabrication process, the semiconductor device shown in FIGS. 2 to 4 may be fabricated.

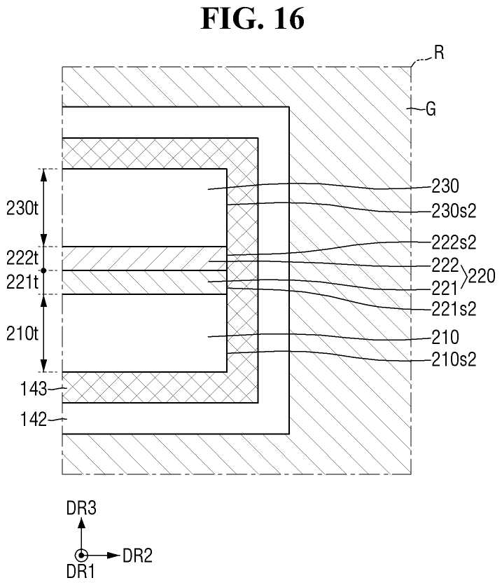

Hereinafter, a semiconductor device according to some embodiments of the present disclosure is described with reference to FIG. 16. Differences from the semiconductor device shown in FIGS. 1 to 4 are the focus of the description.

FIG. 16 is an enlarged view for describing a semiconductor device according to some embodiments of the present disclosure.

Referring to FIG. 16, in a semiconductor device according to some embodiments of the present disclosure, a second layer 220 may include a fourth layer 221 and a fifth layer 222 disposed on the fourth layer 221.

For example, the fourth layer 221 may be on a first layer 210 and in contact with an upper surface of the first layer 210. The fifth layer 222 may be between the fourth layer 221 and a third layer 230 and in contact with each of an upper surface of the fourth layer 221 and a bottom layer of the third layer 230. The fourth layer 221 and the fifth layer 222 may each include silicon carbide (SiC). The atomic ratio of carbon (C) in the fourth layer 221 may be different from the atomic ratio of carbon (C) in the fifth layer 222. Alternatively or additionally, the fourth layer 221 and the fifth layer 222 may have the same lattice structure.

For example, the thickness 221t of the fourth layer 221 in the vertical direction DR3 and the thickness 222t of the fifth layer 222 in the vertical direction DR3 may be less than each of the thickness 210t of the first layer 210 in the vertical direction DR3 and the thickness 230t of the third layer 230 in the vertical direction DR3. For another example, the thickness 221t of the fourth layer 221 in the vertical direction DR3 and the thickness 222t of the fifth layer 222 in the vertical direction DR3 may be the same as each other, but the present disclosure is not limited thereto. For another example, the thickness 210t of the first layer 210 in the vertical direction DR3 and the thickness 230t of the third layer 230 in the vertical direction DR3 may be the same as each other, but the present disclosure is not limited thereto.

For example, a sidewall 210s2 of the first layer 210 in the second horizontal direction DR2, a sidewall 221s2 of the fourth layer 221 in the second horizontal direction DR2, a sidewall 222s2 of the fifth layer 222 in the second horizontal direction DR2, and a sidewall 230s2 of the third layer 230 in the second horizontal direction DR2 may be aligned with one another in the vertical direction DR3. For another example, the sidewall 210s2 of the first layer 210 in the second horizontal direction DR2, the sidewall 221s2 of the fourth layer 221 in the second horizontal direction DR2, the sidewall 222s2 of the fifth layer 222 in the second horizontal direction DR2, and the sidewall 230s2 of the third layer 230 in the second horizontal direction DR2 may each be in contact with an interface layer 143.

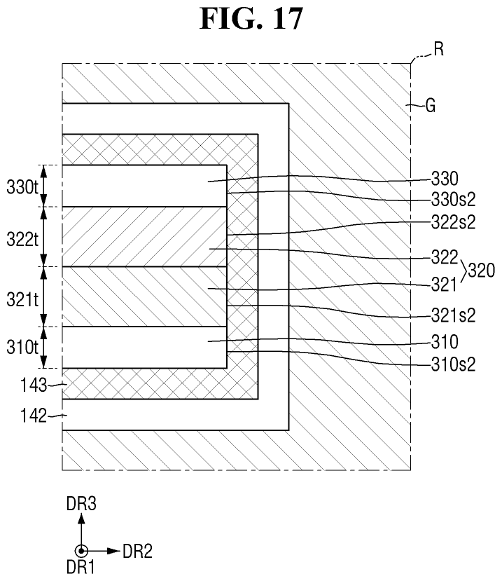

Hereinafter, a semiconductor device according to some embodiments of the present disclosure is described with reference to FIG. 17. Differences from the semiconductor device shown in FIGS. 1 to 4 are the focus of the description.

FIG. 17 is an enlarged view for describing a semiconductor device according to some embodiments of the present disclosure.

Referring to FIG. 17, in a semiconductor device according to some embodiments of the present disclosure, a second layer 320 may include a fourth layer 321 and a fifth layer 322 disposed on the fourth layer 321.

For example, the fourth layer 321 may be on a first layer 310 and in contact with an upper surface of the first layer 310. The fifth layer 322 may be between the fourth layer 321 and a third layer 330 and in contact with each of an upper surface of the fourth layer 321 and a bottom layer of the third layer 330. The fourth layer 321 and the fifth layer 322 may each include silicon carbide (SiC). The atomic ratio of carbon (C) in the fourth layer 321 may be different from the atomic ratio of carbon (C) in the fifth layer 322. Alternatively or additionally, the fourth layer 321 and the fifth layer 322 may have the same lattice structure.

For example, the thickness 321t of the fourth layer 321 in the vertical direction DR3 and the thickness 322t of the fifth layer 322 in the vertical direction DR3 may be less than each of the thickness 310t of the first layer 310 in the vertical direction DR3 and the thickness 330t of the third layer 330 in the vertical direction DR3. For another example, the thickness 321t of the fourth layer 321 in the vertical direction DR3 and the thickness 322t of the fifth layer 322 in the vertical direction DR3 may be the same as each other, but the present disclosure is not limited thereto. For another example, the thickness 310t of the first layer 310 in the vertical direction DR3 and the thickness 330t of the third layer 330 in the vertical direction DR3 may be the same as each other, but the present disclosure is not limited thereto.

For example, a sidewall 310s2 of the first layer 310 in the second horizontal direction DR2, a sidewall 321s2 of the fourth layer 321 in the second horizontal direction DR2, a sidewall 322s2 of the fifth layer 322 in the second horizontal direction DR2, and a sidewall 330s2 of the third layer 330 in the second horizontal direction DR2 may be aligned with one another in the vertical direction DR3. For another example, the sidewall 310s2 of the first layer 310 in the second horizontal direction DR2, the sidewall 321s2 of the fourth layer 321 in the second horizontal direction DR2, the sidewall 322s2 of the fifth layer 322 in the second horizontal direction DR2, and the sidewall 330s2 of the third layer 330 in the second horizontal direction DR2 may each be in contact with an interface layer 143.

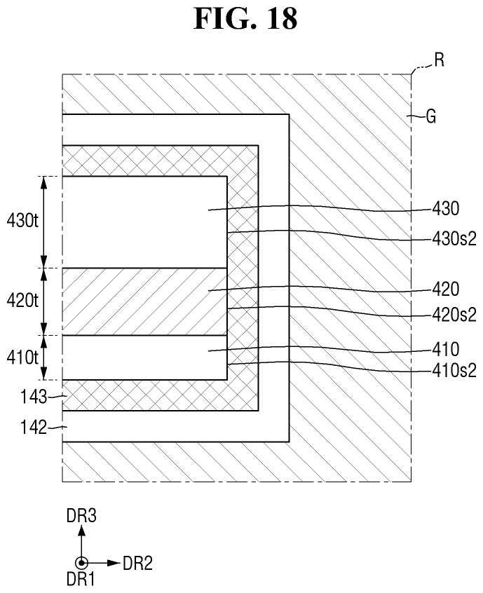

Hereinafter, a semiconductor device according to some embodiments of the present disclosure is described with reference to FIG. 18. Differences from the semiconductor device shown in FIGS. 1 to 4 are the focus of the description.

FIG. 18 is an enlarged view for describing a semiconductor device according to some embodiments of the present disclosure.

Referring to FIG. 18, in a semiconductor device according to some embodiments of the present disclosure, a thickness 430t of a third layer 430 in the vertical direction DR3 may be greater than a thickness 410t of a first layer 410 in the vertical direction DR3. Alternatively or additionally, the thickness 410t of the first layer 410 in the vertical direction DR3 may be greater than a thickness 420t of a second layer 420 in the vertical direction DR3.

For example, a sidewall 410s2 of the first layer 410 in the second horizontal direction DR2, a sidewall 420s2 of the second layer 420 in the second horizontal direction DR2, and a sidewall 430s2 of the third layer 430 in the second horizontal direction DR2 may be aligned with one another in the vertical direction DR3. For another example, the sidewall 410s2 of the first layer 410 in the second horizontal direction DR2, the sidewall 420s2 of the second layer 420 in the second horizontal direction DR2, and the sidewall 430s2 of the third layer 430 in the second horizontal direction DR2 may each be in contact with an interface layer 143.

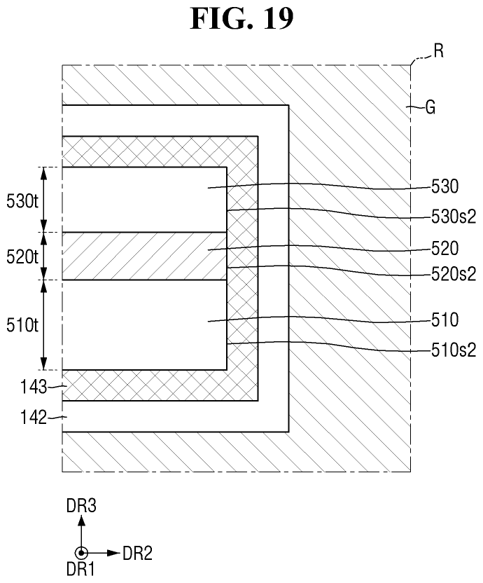

Hereinafter, a semiconductor device according to some embodiments of the present disclosure is described with reference to FIG. 19. Differences from the semiconductor device shown in FIGS. 1 to 4 are the focus of the description.

FIG. 19 is an enlarged view for describing a semiconductor device according to some embodiments of the present disclosure.

Referring to FIG. 19, in a semiconductor device according to some embodiments of the present disclosure, a thickness 530t of a third layer 530 in the vertical direction DR3 may be less than a thickness 510t of a first layer 510 in the vertical direction DR3. Alternatively or additionally, a thickness 520t of a second layer 520 in the vertical direction DR3 may be less than the thickness 530t of the third layer 530 in the vertical direction DR3.

For example, a sidewall 510s2 of the first layer 510 in the second horizontal direction DR2, a sidewall 520s2 of the second layer 520 in the second horizontal direction DR2, and a sidewall 530s2 of the third layer 530 in the second horizontal direction DR2 may be aligned with one another in the vertical direction DR3. For another example, the sidewall 510s2 of the first layer 510 in the second horizontal direction DR2, the sidewall 520s2 of the second layer 520 in the second horizontal direction DR2, and the sidewall 530s2 of the third layer 530 in the second horizontal direction DR2 may each be in contact with an interface layer 143.

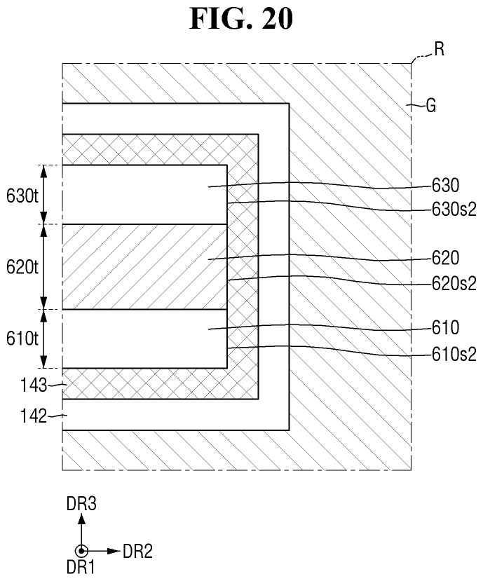

Hereinafter, a semiconductor device according to some embodiments of the present disclosure is described with reference to FIG. 20. Differences from the semiconductor device shown in FIGS. 1 to 4 are the focus of the description.

FIG. 20 is an enlarged view for describing a semiconductor device according to some embodiments of the present disclosure.

Referring to FIG. 20, in a semiconductor device according to some embodiments of the present disclosure, a thickness 620t of a second layer 620 in the vertical direction DR3 may be greater than each of a thickness 610t of a first layer 610 in the vertical direction DR3 and a thickness 630t of a third layer 630 in the vertical direction DR3. For example, the thickness 610t of the first layer 610 in the vertical direction DR3 and the thickness 630t of the third layer 630 in the vertical direction DR3 may be the same as each other, but the present disclosure is not limited thereto.

For example, a sidewall 610s2 of the first layer 610 in the second horizontal direction DR2, a sidewall 620s2 of the second layer 620 in the second horizontal direction DR2, and a sidewall 630s2 of the third layer 630 in the second horizontal direction DR2 may be aligned with one another in the vertical direction DR3. For another example, the sidewall 610s2 of the first layer 610 in the second horizontal direction DR2, the sidewall 620s2 of the second layer 620 in the second horizontal direction DR2, and the sidewall 630s2 of the third layer 630 in the second horizontal direction DR2 may each be in contact with an interface layer 143.

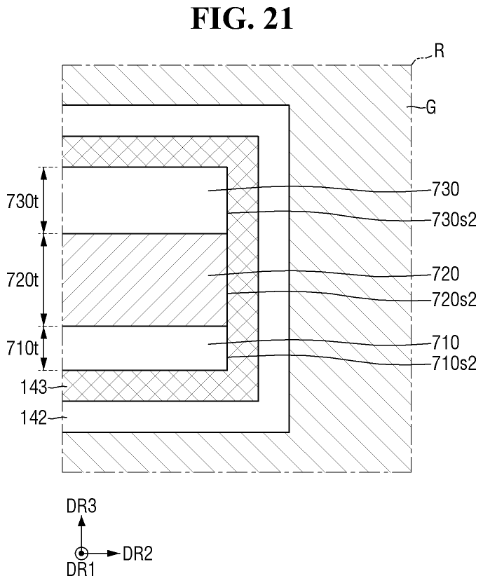

Hereinafter, a semiconductor device according to some embodiments of the present disclosure is described with reference to FIG. 21. Differences from the semiconductor device shown in FIGS. 1 to 4 are the focus of the description.

FIG. 21 is an enlarged view for describing a semiconductor device according to some embodiments of the present disclosure.

Referring to FIG. 21, in a semiconductor device according to some embodiments of the present disclosure, a thickness 720t of a second layer 720 in the vertical direction DR3 may be greater than each of a thickness 710t of a first layer 710 in the vertical direction DR3 and a thickness 730t of a third layer 730 in the vertical direction DR3. Alternatively or additionally, the thickness 730t of the third layer 730 in the vertical direction DR3 may be greater than the thickness 710t of the first layer 710 in the vertical direction DR3.

For example, a sidewall 710s2 of the first layer 710 in the second horizontal direction DR2, a sidewall 720s2 of the second layer 720 in the second horizontal direction DR2, and a sidewall 730s2 of the third layer 730 in the second horizontal direction DR2 may be aligned with one another in the vertical direction DR3. For another example, the sidewall 710s2 of the first layer 710 in the second horizontal direction DR2, the sidewall 720s2 of the second layer 720 in the second horizontal direction DR2, and the sidewall 730s2 of the third layer 730 in the second horizontal direction DR2 may each be in contact with an interface layer 143.

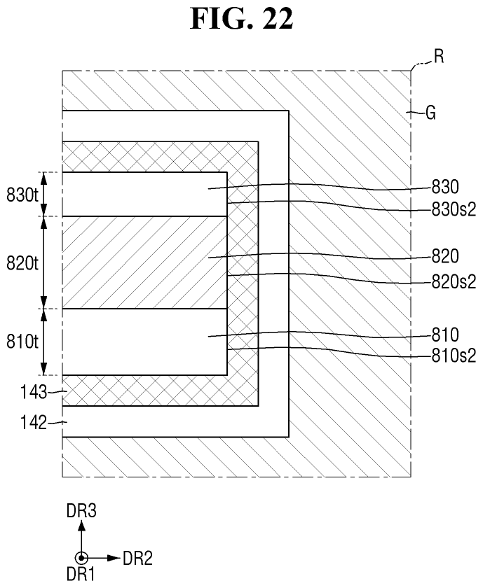

Hereinafter, a semiconductor device according to some embodiments of the present disclosure is described with reference to FIG. 22. Differences from the semiconductor device shown in FIGS. 1 to 4 are the focus of the description.

FIG. 22 is an enlarged view for describing a semiconductor device according to some embodiments of the present disclosure.

Referring to FIG. 22, in a semiconductor device according to some embodiments of the present disclosure, a thickness 820t of a second layer 820 in the vertical direction DR3 may be greater than each of a thickness 810t of a first layer 810 in the vertical direction DR3 and a thickness 830t of a third layer 830 in the vertical direction DR3. Alternatively or additionally, the thickness 810t of the first layer 810 in the vertical direction DR3 may be greater than the thickness 830t of the third layer 830 in the vertical direction DR3.

For example, a sidewall 810s2 of the first layer 810 in the second horizontal direction DR2, a sidewall 820s2 of the second layer 820 in the second horizontal direction DR2, and a sidewall 830s2 of the third layer 830 in the second horizontal direction DR2 may be aligned with one another in the vertical direction DR3. For another example, the sidewall 810s2 of the first layer 810 in the second horizontal direction DR2, the sidewall 820s2 of the second layer 820 in the second horizontal direction DR2, and the sidewall 830s2 of the third layer 830 in the second horizontal direction DR2 may each be in contact with an interface layer 143.

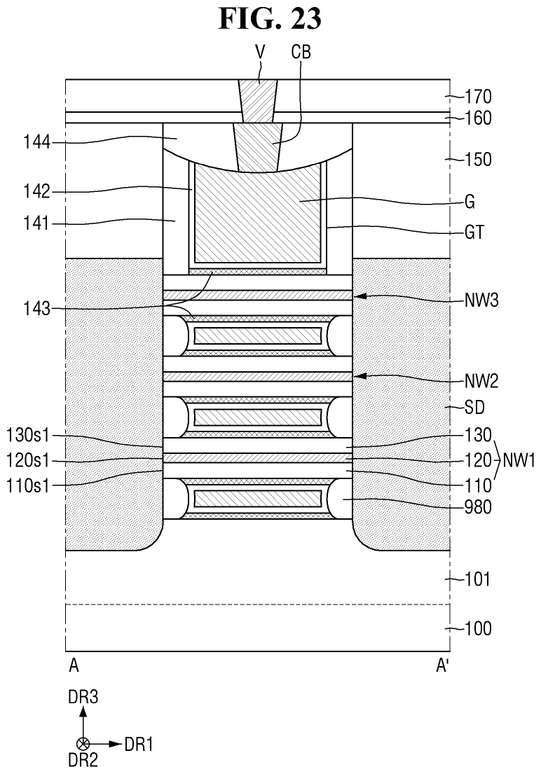

Hereinafter, a semiconductor device according to some embodiments of the present disclosure is described with reference to FIG. 23. Differences from the semiconductor device shown in FIGS. 1 to 4 are the focus of the description.

FIG. 23 is a cross-sectional view for describing a semiconductor device according to some embodiments of the present disclosure.

Referring to FIG. 23, in a semiconductor device according to some embodiments of the present disclosure, inner spacers 980 may be disposed between a gate electrode G and a source/drain region SD.

For example, the inner spacers 980 may disposed on both sidewalls of the gate electrode G in the first horizontal direction DR1 between an active pattern 101 and a first nanosheet NW1, between the first nanosheet NW1 and a second nanosheet NW2, and between the second nanosheet NW2 and a third nanosheet NW3. The inner spacers 980 may be in contact with a gate insulation layer 142 and the source/drain region SD.

While the present disclosure has been particularly shown and described with reference to embodiments thereof and using specific terms, these embodiments are provided so that this disclosure will fully convey the concept of the present disclosure, and not for purposes of limitation. Thus, it will be obvious to one of ordinary skill in the art that various changes and other equivalents may be made therein. Therefore, the scope of the present disclosure is defined not by the detailed description of the present disclosure but by the appended claims.

What is claimed is:

1. A semiconductor device, comprising:
a substrate;
an active pattern that extends in a first horizontal direction on the substrate;
a first nanosheet that is spaced apart from the active pattern in a vertical direction, and comprises a plurality of layers, wherein the plurality of layers comprises:
a first layer,
a second layer disposed on the first layer and in contact with the first layer, and
a third layer disposed on the second layer and in contact with the second layer,
wherein the first layer and the third layer include a first material, and
wherein the second layer includes a second material that is different from the first material;
a second nanosheet disposed on the first nanosheet and spaced apart from the first nanosheet in the vertical direction; and
a gate electrode that extends in a second horizontal direction on the active pattern and surrounds the first nanosheet and the second nanosheet, wherein the second horizontal direction is different from the first horizontal direction.

2. The semiconductor device of claim 1, wherein the first material contains silicon (Si) and the second material contains silicon carbide (SiC).

3. The semiconductor device of claim 1, wherein each sidewall in the second horizontal direction of the plurality of layers is aligned in the vertical direction to remaining sidewalls in the second horizontal direction of the plurality of layers.

4. The semiconductor device of claim 1, further comprising:
a gate insulation layer disposed between the gate electrode and each sidewall in the second horizontal direction of the plurality of layers.

5. The semiconductor device of claim 4, further comprising:
an interface layer disposed between the gate insulation layer and the sidewalls in the second horizontal direction of the plurality of layers, and that is in contact with the sidewalls in the second horizontal direction of the plurality of layers.

6. The semiconductor device of claim 1, wherein a second thickness of the second layer in the vertical direction is different from a first thickness of the first layer in the vertical direction.

7. The semiconductor device of claim 6, wherein the second thickness of the second layer in the vertical direction is less than the first thickness of the first layer in the vertical direction.

8. The semiconductor device of claim 6, wherein the second thickness of the second layer in the vertical direction is greater than the first thickness of the first layer in the vertical direction.

9. The semiconductor device of claim 1, wherein a third thickness of the third layer in the vertical direction is different from a first thickness of the first layer in the vertical direction.

10. The semiconductor device of claim 9, wherein the third thickness of the third layer in the vertical direction is greater than the first thickness of the first layer in the vertical direction.

11. The semiconductor device of claim 9, wherein the third thickness of the third layer in the vertical direction is less than the first thickness of the first layer in the vertical direction.

12. The semiconductor device of claim 1, further comprising:
an inner spacer disposed on a sidewall of the gate electrode in the first horizontal direction, between the first nanosheet and the second nanosheet.

13. A semiconductor device, comprising:
a substrate;
an active pattern which that extends in a first horizontal direction on the substrate;
a first nanosheet that is spaced apart from the active pattern in a vertical direction, and comprises a plurality of layers, wherein the plurality of layers comprises:
a first layer containing silicon (Si),
a second layer disposed on the first layer and in contact with the first layer and containing silicon carbide (SiC), and
a third layer disposed on the second layer and in contact with the second layer and containing silicon (Si);
a gate electrode that extends in a second horizontal direction on the active pattern and surrounds the first nanosheet, wherein the second horizontal direction is different from the first horizontal direction; and
a source/drain region disposed on at least one side of the gate electrode in the first horizontal direction, and in contact with each sidewall in the first horizontal direction of the plurality of layers.

14. The semiconductor device of claim 13, wherein the second layer comprises:
a fourth layer in contact with the first layer,
a fifth layer disposed between the fourth layer and the third layer and is in contact with the third layer and the fourth layer, and
an atomic ratio of carbon (C) in the fourth layer is different from an atomic ratio of carbon (C) in the fifth layer.

15. The semiconductor device of claim 14, wherein:
a fourth thickness of the fourth layer in the vertical direction is less than a first thickness of the first layer in the vertical direction, and
a fifth thickness of the fifth layer in the vertical direction is less than the first thickness of the first layer in the vertical direction.

16. The semiconductor device of claim 14, wherein:
a fourth thickness of the fourth layer in the vertical direction is greater than a first thickness of the first layer in the vertical direction, and
a fifth thickness of the fifth layer in the vertical direction is greater than the first thickness of the first layer in the vertical direction.

17. The semiconductor device of claim 13, further comprising:
a second nanosheet disposed on the first nanosheet, spaced apart from the first nanosheet in the vertical direction, and surrounded by the gate electrode.

18. The semiconductor device of claim 13, wherein a second thickness of the second layer in the vertical direction is different from a first thickness of the first layer in the vertical direction.

19. The semiconductor device of claim 13, wherein a third thickness of the third layer in the vertical direction is different from a first thickness of the first layer in the vertical direction.

20. A semiconductor device comprising:
a substrate;
an active pattern that extends in a first horizontal direction on the substrate;
a plurality of nanosheets that are stacked and spaced apart from the active pattern in a vertical direction;
a gate electrode that extends in a second horizontal direction on the active pattern and surrounds the plurality of nanosheets, the second horizontal direction being different from the first horizontal direction;
a source/drain region disposed on at least one side of the gate electrode in the first horizontal direction;
a gate insulation layer disposed between the plurality of nanosheets and the gate electrode; and
an interface layer disposed between the plurality of nanosheets and the gate insulation layer,
wherein each of the plurality of nanosheets comprises a plurality of layers, wherein the plurality of layers comprises a first layer containing silicon (Si), a second layer disposed on the first layer and in contact with the first layer and containing silicon carbide (SiC), and a third layer disposed on the second layer and in contact with the second layer and containing silicon (Si),
a first sidewall in the first horizontal direction of each of the plurality of layers is in contact with the source/drain region,
a second sidewall in the second horizontal direction of each of the plurality of layers is in contact with the interface layer,
a second thickness of the second layer in the vertical direction is less than a first thickness of the first layer in the vertical direction, and
the second thickness of the second layer in the vertical direction is less than a third thickness of the third layer in the vertical direction.
